(19) United States
(12) Patent Application Publication
(10) Pub. No.: US 2024/0088889 A1
(43) Pub. Date: Mar. 14, 2024

(54) METHOD FOR DRIVING A TOPOLOGICAL SEMICONDUCTOR SWITCH FOR A POWER ELECTRONICS SYSTEM

(71) Applicant: ZF Friedrichshafen AG, Friedrichshafen (DE)

(72) Inventor: Fabian Hohmann, Hofbieber (DE)

(73) Assignee: ZF Friedrichshafen AG, Friedrichshafen (DE)

(21) Appl. No.: 18/457,574

(22) Filed: Aug. 29, 2023

(30) Foreign Application Priority Data
Sep. 13, 2022 (DE) 102022209531.6

(51) Int. Cl. H03K 17/12; H03K 17/567

(52) U.S. Cl. CPC H03K 17/127; H03K 17/567; H03K 2017/0806

(57) ABSTRACT

A method for driving a topological semiconductor switch for a power electronics system, wherein the topological semiconductor switch is split into at least two groups of power semiconductors, wherein, when an active short circuit is identified, switchover from the power semiconductor which conducts the short circuit first to the other power semiconductor takes place.

### CROSS-REFERENCE TO RELATED APPLICATION

This application claims priority to German Application No. DE 10 2022 209 531.6, filed on Sep. 13, 2022, the entirety of which is hereby fully incorporated by reference herein.

### FIELD

The present invention relates to the field of electric mobility, in particular of electronics modules.

### BACKGROUND AND SUMMARY

The use of electronics modules, for example power electronics modules, in motor vehicles has significantly increased in recent decades. This can be attributed firstly to the need to improve the fuel saving and the vehicle performance and secondly to the advances in semiconductor technology.

Inverters, also referred to as power converters, require a power module or a semiconductor package in order that the direct current originating from a battery or the rechargeable battery is converted into alternating current. The power module has topological switches having power transistors which are used for controlling the currents and for generating the alternating current. In this case, different configurations of power transistors are known. Inter alia, it is known to use so-called MOSFETs (metal-oxide semiconductor field-effect transistors) or IGBTs (insulated-gate bipolar transistors). The semiconductor material used in this case can be silicon (Si), silicon carbide (SiC), gallium nitride (GaN) or any other semiconductor material. Also already known is the use of different semiconductor types in a topological semiconductor switch, i.e., for example, a combination of SiC-MOSFET and Si-IGBT. In order to operate the latter in parallel, different drive methods are known, for example an XOR operating mode, in which in each case only one of the semiconductor switches is active. Owing to the reduced semiconductor area of each power semiconductor, however, primarily fault cases are critical since in this case only the reduced chip area is available.

Therefore, the invention is based on the object of providing an improved method for driving a topological semiconductor switch for a power electronics system in the fault case.

This object is achieved by the features of the independent claims. Advantageous configurations are the subject matter of the dependent claims.

What is proposed is a method for driving a topological semiconductor switch for a power electronics system, wherein the topological semiconductor switch is split into at least two groups of power semiconductors, wherein, when an active short circuit is identified, switchover from the power semiconductor which conducts the short circuit first to the other power semiconductor takes place.

In one configuration, provision is made for the switchover to take place immediately on identification or at a current minimum.

In one configuration, provision is made for, in the case where both power semiconductors have a gate resistance designed for an ASC fault case, a continuous switchover between the power semiconductors to take place when a preset temperature of one of the power semiconductors is reached or exceeded.

In one configuration, provision is made for, in order to prevent overvoltages, a soft turnoff to be used for switching off the power semiconductors by virtue of the fact that, in the case where no current information is present and a soft turnoff gate resistance is present, said gate resistance is used or the soft turnoff is implemented by external circuitry or a gate resistance of the power semiconductor is designed and used as a soft turnoff resistance.

In addition, a power electronics module is proposed, having at least one topological semiconductor switch which is split into at least two groups of power semiconductors and a control unit, which is designed for driving the topological semiconductor switch using the method.

In one configuration, provision is made for the power semiconductors in the groups to consist of different semiconductor materials and/or different semiconductor types and/or different semiconductor areas.

In one configuration, provision is made for one of the power semiconductors to be an SiC-MOSFET and the other to be an Si-IGBT.

In addition, an inverter is provided, having the power electronics module. In addition, an electric drive of a vehicle is provided, having the inverter. Likewise, a motor vehicle is provided, having an electric motor driven by means of the electric drive.

Further features and advantages of the invention can be gleaned from the description below of exemplary embodiments of the invention, with reference to the figures in the drawings which show details according to the invention, and from the claims. The individual features can be implemented in each case individually or together in any desired combination in one variant of the invention.

Preferred embodiments of the invention are explained in more detail below with reference to the attached drawings.

### BRIEF DESCRIPTION OF THE DRAWINGS

FIG. 1 shows a basic design of a topological semiconductor switch in accordance with one embodiment of the present invention.

FIG. 2 shows the principle of XOR driving of the topological semiconductor switch shown in FIG. 1.

FIG. 3 shows simulated graphs of an ASC current, an ASC power and an ASC temperature over time as is conventional in accordance with the prior art.

FIGS. 4 and 5 each show simulated graphs of an ASC current, an ASC power and an ASC temperature over time in accordance with two different embodiments of the present invention.

FIG. 6 shows simulated graphs with continuous switchover of an ASC current, an ASC power and an ASC temperature over time in accordance with one embodiment of the present invention.

FIG. 7 shows a motor vehicle having an inverter and a control device in accordance with one embodiment of the present invention.

### DETAILED DESCRIPTION

In the descriptions of the figures below, identical elements or functions are provided with the same reference signs.

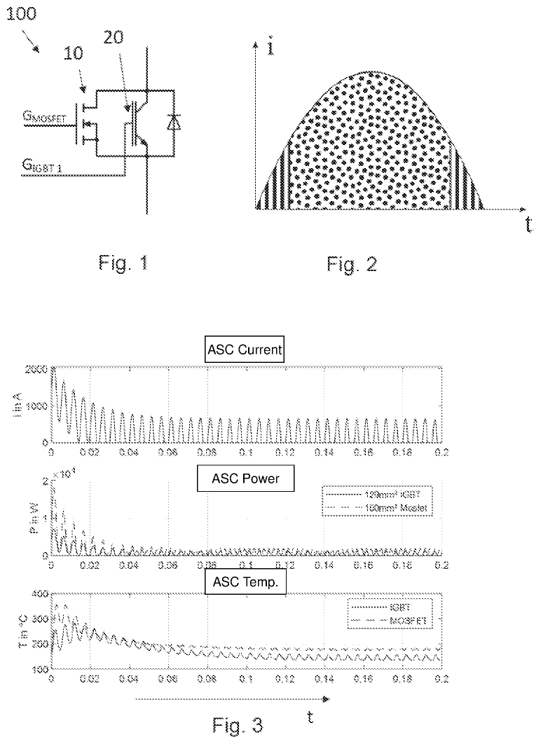

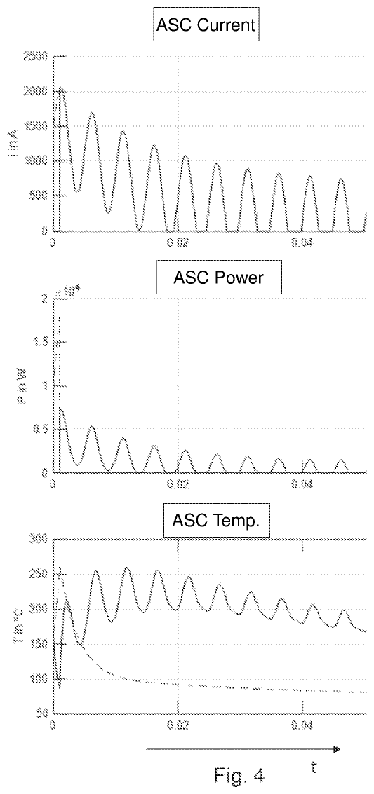

The parallel operation of topological semiconductor switches 100 of different semiconductor groups, for example a silicon carbide (SiC) MOSFET 10 and a silicon (Si) IGBT 20, as shown in FIG. 1, is possible by virtue of a plurality of drive methods which are all implemented by a corresponding driver as control unit 200. A promising method is in this case the temporally separate driving of the semiconductors, so-called XOR driving, as illustrated in FIG. 2. In this case, in each case only one semiconductor group takes over the total current. For example, in the striped region the silicon carbide MOSFET 10 is conducting, whereas the dotted (central) region is taken over by the silicon IGBT 20. The XOR driving enables a plurality of advantages, for example optimized gate resistances GMOSFET, GIGBT1. In addition, only one current sensor is necessary, etc.

As already mentioned, the reduced semiconductor area of each power semiconductor is critical in the XOR operating mode primarily in the fault case since in this case only the reduced chip area is available. In relation to the software and safety architecture, however, it is advantageous to remain in XOR driving. Error handling with a single semiconductor material can represent an overload, however.

FIG. 3 shows a simulation of the temperatures of an ASC current (ASC=active short circuit, uppermost graph) if it were to be placed in each case only with the area of the MOSFET 10 (dashed line) or only the area of the IGBT 20 (continuous line) (middle graph). With the MOSFET area, a maximum temperature of 356° C. is achieved, and with the IGBT area, a maximum temperature of 281° C. (lowermost graph).

The aim of the invention is to reduce the thermal loading of the power semiconductor 10 or 20 taking up the current in the fault case.

In order to solve the problem, an adapted XOR driving is proposed for the fault case of the ASC (active short circuit), also referred to as ASC fault case for short. The typical fault current in the active short circuit ASC is an exponentially decaying sinusoidal current, as is illustrated in the uppermost graph in FIG. 3.

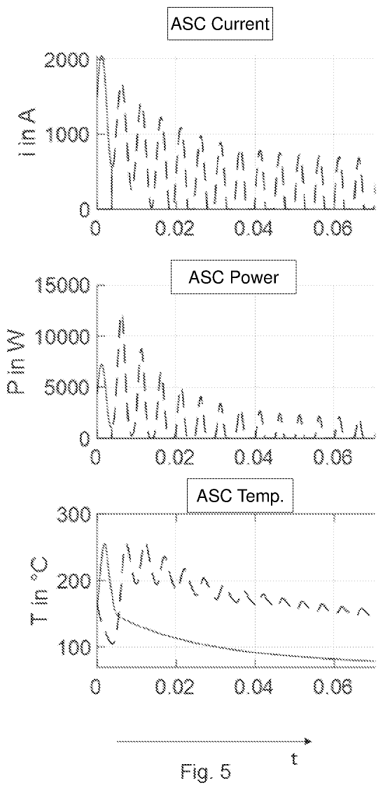

The short-circuit time (in FIG. 3 between t=0 and approximately t=0.02) at the start of the fault case requires the highest energy input into the power semiconductor 10, 20, as can be seen in the middle graph, wherein the dashed line represents the energy input into the MOSFET 10 and the continuous line represents the energy input into the IGBT. The method according to the invention proposes conducting this beginning part of the short-circuit current through the other power semiconductor type (power semiconductor 10 or 20). Therefore, a reduction in the maximum temperature T (lowermost graph) of the two power semiconductors 10, 20 can be achieved, as is illustrated in FIGS. 4 and 5. FIGS. 4 and 5 show only the detail of the graph which is relevant for the method, i.e. in particular the time span of the ASC.

It can be seen here that, in the case of an ASC, switchover from the power semiconductor 10, 20 carrying the short circuit first to the other power semiconductor 10, 20 takes place as soon as the ASC is identified (uppermost graph). In this case, it can be seen that the two power semiconductors 10, 20 reach a maximum temperature of approximately 250° C. (lowermost graph). In relation to the MOSFET 10, the maximum temperature can thus be reduced by approximately 30% and for the IGBT by approximately 7%. In FIG. 4, short-circuit current (uppermost graph) and power (middle graph) are conducted first by the MOSFET 10, and in FIG. 5 first by the IGBT 20.

In FIGS. 4 and 5 as well, the MOSFET 10 is again illustrated as a dashed line and the IGBT 20 is again illustrated as a continuous line.

The maximum energy input and the optimum switchover time are dependent on various parameters, inter alia on the speed of the motor vehicle 300, the design of the electric motor and the maximum power of the drive. In addition, the short-circuit strength of each semiconductor type is dependent on the nature of the inverter 400, i.e. inter alia its cooling link, semiconductor area, ratio of (SiC-)MOSFET to (Si-)IGBT. Depending on the entire drive system, an optimum switchover time which needs to be designed for the three-phase worst case scenario results.

Depending on the safety architecture, the switchover takes place immediately after identification of the ASC or at a current minimum in order to prevent an overvoltage at the power semiconductor 10, 20. An identification of the ASC can take place by a person skilled in the art in a known manner, for example via a driver circuit.

If no current information is present, the use of a soft turnoff gate resistance is expedient which can prevent the overvoltage. This is used to switch off both power semiconductors 10, 20 slowly in order to prevent an overvoltage.

If the driver should not provide a soft turnoff functionality, this can be implemented by external circuitry.

A further possibility consists in that the “normal” gate resistance of the power semiconductor 10, 20 is designed for this fault case and provides a soft turnoff. The on time of the first power semiconductor 10 or 20 can therefore be designed with a fixed time for the worst case scenario. As a result, no further information is necessary in the fault case.

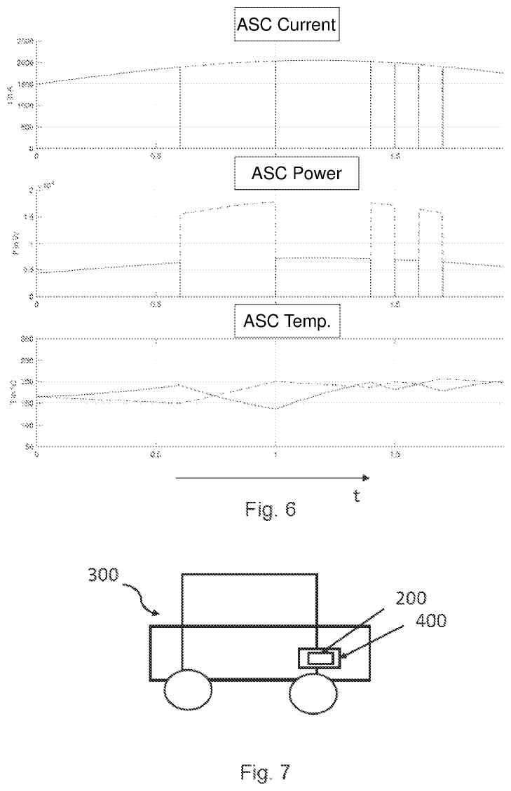

If both power semiconductors 10, 20 have an increased gate resistance for the short-circuit case, a continuous switchover can take place in order to further limit the maximum temperature of each power semiconductor 10, 20. In the example in FIG. 6, this is shown for a maximum temperature of 200° C. That is to say that when this temperature is reached by one of the power semiconductors 10, 20, switchover to the other one takes place. This can in turn take place immediately or at a current minimum. The respective on durations of each power semiconductor 10, 20 are in this case again dependent on the entire system.

By virtue of the proposed method for driving a topological semiconductor switch 100 for a power electronics system having hybrid semiconductor switches 100, i.e. semiconductor switches 100 which are formed from at least two groups of power semiconductors 10, 20, in the fault case of the active short circuit ASC an optimized temperature distribution among the power semiconductors 10, 20 can be realized and therefore the life of the power semiconductors 10, 20 can be extended. Groups of power semiconductors 10, 20 should be understood to mean that the power semiconductors 10, 20 used can have different properties, i.e. consist of different materials such as Si, SiC, GaN etc., and/or can have different types such as MOSFET, IGBT, JFET etc. and/or different areas.

A power electronics module within the scope of this invention is used to operate an electric drive of a vehicle, in particular an electric vehicle and/or a hybrid vehicle, and/or electrified axles. The electronics module comprises an inverter. It can also comprise a rectifier, a DC/DC converter, a transformer and/or another electrical converter or part of such a converter or some of them. In particular, the electronics module is used for supplying current to an electric machine, for example an electric motor and/or a generator. An inverter is preferably used to generate a polyphase alternating current from a direct current generated by means of a DC voltage of an energy source, for example a battery.

Inverters 400 for electric drives of motor vehicles 300, in particular passenger cars and utility vehicles, and buses, are designed for the high voltage range and are in particular designed in a blocking voltage class of above approximately 650 volts.

The described circuit arrangement is used, for example, in inverters 400 which are installed in motor vehicles 300, as is shown in FIG. 7. The motor vehicle 300 can have in particular an electrically driven axle. The motor vehicle 300 can in principle be in the form of a purely internal combustion engine-based motor vehicle, in the form of a hybrid motor vehicle or in the form of an electric vehicle.

### LIST OF REFERENCE SIGNS

100 semiconductor switch
10 MOSFET
20 IGBT
200 control unit
300 motor vehicle
400 inverter
G_{MOSFET} gate MOSFET
G_{IGBT1} gate IGBT
ASC active short circuit
i current
t time
T, temp. temperature
P power

1. A method for driving a topological semiconductor switch for a power electronics system, wherein the topological semiconductor switch is split into at least two groups of power semiconductors, the method comprising:
switching over from a power semiconductor that first conducts a short circuit to another power semiconductor in response to an active short circuit being identified.

2. The method according to claim 1, wherein the switchover takes place immediately on identification or at a current minimum.

3. The method according to claim 1, comprising:
implementing a soft turnoff to prevent overvoltages, including, in response to no current information being present and a soft turnoff gate resistance being present, using the gate resistance.

4. The method according to claim 1, comprising:
implementing a soft turnoff to prevent overvoltages by external circuitry.

5. The method according to claim 1, comprising:
implementing a soft turnoff to prevent overvoltages, including, using a gate resistance of the power semiconductor as a soft turnoff resistance.

6. The method according to claim 1, comprising:
implementing a continuous switchover between the power semiconductors in response to a preset temperature of one of the power semiconductors being reached or exceeded, wherein the at least two groups of power semiconductors both have a gate resistance designed for an active short circuit (ASC) fault case.

7. A power electronics device, comprising:
at least one topological semiconductor switch which is split into at least two groups of power semiconductors; and
a controller configured to drive the topological semiconductor switch and switch over from a power semiconductor that first conducts a short circuit to another power semiconductor in response to an active short circuit being identified.

8. The power electronics device according to claim 7, wherein the power semiconductors in the at least two groups consist of different semiconductor materials.

9. The power electronics device according to claim 7, wherein the power semiconductors in the at least two groups consist of different semiconductor types.

10. The power electronics device according to claim 7, wherein the power semiconductors in the at least two groups consist of different semiconductor areas.

11. The power electronics device according to claim 9, wherein one of the at least two groups of power semiconductors is an SiC-MOSFET and the other is an Si-IGBT.

12. The power electronics device according to claim 7, wherein the controller is configured to:
cause the switchover to takes place immediately on identification or at a current minimum.

13. The power electronics device according to claim 7, wherein the controller is configured to:
implement a soft turnoff to prevent overvoltages, including, in response to no current information being present and a soft turnoff gate resistance being present, using the gate resistance.

14. The power electronics device according to claim 7, wherein the controller is configured to:
implement a soft turnoff to prevent overvoltages, including, using a gate resistance of the power semiconductor as a soft turnoff resistance.

15. The power electronics device according to claim 7, wherein the controller is configured to:
implement a continuous switchover between the power semiconductors in response to a preset temperature of one of the power semiconductors being reached or exceeded, wherein the at least two groups of power semiconductors both have a gate resistance designed for an active short circuit (ASC) fault case.

16. An inverter, comprising:
the power electronics device according to claim 7.

17. An electric drive of a motor vehicle comprising:
the inverter according to claim 16.

18. A motor vehicle comprising:
an electric motor driven by the electric drive according to claim 17.
